(19) United States
(12) Patent Application Publication
(10) Pub. No.: US 2026/0033162 A1
(43) Pub. Date: Jan. 29, 2026

(54) DISPLAY PANEL, MANUFACTURING METHOD THEREOF, AND DISPLAY APPARATUS

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/263,541

(22) Filed: Jul. 9, 2025

(30) Foreign Application Priority Data
Jul. 23, 2024 (CN) 202410994771.0

(51) Int. Cl. H10K 59/123; H10K 59/12

(52) U.S. Cl. CPC H10K 59/123; H10K 59/1201

(57) ABSTRACT

The present application provides a display panel, a manufacturing method thereof, and a display apparatus. The display panel includes a driving substrate, a glass substrate, multiple conductive portions, and a light-emitting component layer. The driving substrate includes multiple driving electrodes. An insulating protective layer is defined with multiple electrode via-holes, each exposing a driving electrode and forms a first gap with the driving electrode. The glass substrate is attached to the insulating protective layer and is defined with multiple glass through-holes aligned with electrode via-holes. Each conductive portion includes a first conductive layer and a second conductive layer. The first conductive layer coats a driving electrode and forms a second gap with the electrode via-hole. The second conductive layer surrounds the first conductive layer and fills the second gap and a third gap. The third gap is between the first conductive layer and the glass through-holes.

### CROSS REFERENCE TO RELATED APPLICATIONS

The present disclosure claims priority to Chinese patent application No. 202410994771.0 filed on Jul. 23, 2024, the entire contents of which are incorporated herein by reference.

### TECHNICAL FIELD

The present disclosure relates to the field of display technologies, and in particular to a display panel, a manufacturing method thereof, and a display apparatus.

### BACKGROUND

A single-crystal silicon driving backplane is a driving substrate formed with semiconductor components manufactured by complementary metal oxide semiconductor (CMOS) processes as driving units. Compared with a conventional active-matrix organic light-emitting diode (AMOLED) panel using amorphous silicon, microcrystalline silicon, or low-temperature polycrystalline silicon thin-film transistors as a backplane, the single-crystal silicon driving backplane has higher carrier mobility. Therefore, a silicon-based organic light-emitting diode (OLED) display panel is currently a type of display panel with the best performance among products applied in the AR/VR field.

At present, the silicon-based OLED display panel integrates traditional externally bonded display chips into a silicon-based driving backplane. A manufacturing method thereof involves evaporating and fabricating OLED light-emitting components on a silicon-based driving substrate. Specifically, an anode is first deposited, then a pixel definition layer is fabricated, followed by sequentially depositing an organic light-emitting layer and a cathode. In this way, smaller-sized pixel units can be fabricated, achieving a display fineness beyond the retinal level, with advantages such as high resolution, high integration, low power consumption, small size, and light weight.

However, directly evaporating and fabricating OLED light-emitting components on the silicon-based driving substrate may easily affect a silicon-based driving circuit, leading to damage to the circuit and causing the circuit to be unusable, thereby increasing costs.

### SUMMARY OF THE DISCLOSURE

In order to solve the problems mentioned above, a first technical solution provided by the present disclosure is a display panel. The display panel includes a driving substrate, a glass substrate, a plurality of conductive portions, and a light-emitting component layer. The driving substrate includes a driving circuit layer, and a bonding electrode layer and an insulating protective layer arranged on a side of the driving circuit layer. The bonding electrode layer includes a plurality of driving electrodes electrically connected to the driving circuit layer. The insulating protective layer has a plurality of electrode via-holes defined therein, each of the electrode via-holes exposes a corresponding one of the driving electrodes, and a first gap is formed between an inner wall surface of each of the electrode via-holes and the corresponding one of the driving electrodes. The glass substrate is attached to a side of the insulating protective layer away from the driving circuit layer. The glass substrate has a plurality of glass through-holes defined therein and is aligned with the electrode via-holes respectively, and an aperture of each of the glass through-holes is not smaller than an aperture of a corresponding one of the electrode via-holes. Each of the conductive portions penetrates through a corresponding one of the glass through-holes and a corresponding one of the electrode via-holes, and includes a first conductive layer and a second conductive layer. The first conductive layer coats an exposed surface of a corresponding one of the driving electrodes, and a second gap is formed between the first conductive layer and an inner wall surface of the corresponding one of the electrode via-holes; the second conductive layer surrounds a side surface of the first conductive layer and fills the second gap and a third gap, and the third gap is formed between the first conductive layer and an inner wall surface of the corresponding one of the glass through-holes; the first conductive layer includes an inert conductor with toughness, and the second conductive layer includes an elastic conductor. The light-emitting component layer includes a plurality of light-emitting units arranged on a side of the glass substrate away from the driving substrate. An electrode of each of the light-emitting units covers a corresponding one of the conductive portions and is in contact with and electrically connected to the corresponding one of the conductive portions.

In order to solve the problems mentioned above, a second technical solution provided by the present disclosure is a manufacturing method, configured to manufacture the display panel according to any one of embodiments mentioned above. The manufacturing method includes steps of: forming a driving substrate, including: providing a silicon substrate and forming a driving circuit layer on the silicon substrate; forming a bonding electrode layer and an insulating protective layer on the driving circuit layer; the bonding electrode layer including a plurality of driving electrodes electrically connected to the driving circuit layer, the insulating protective layer having a plurality of electrode via-holes defined therein, each of the electrode via-holes exposing a corresponding one of the driving electrodes, and a first gap being formed between an inner wall surface of each of the electrode via-holes and the corresponding one of the driving electrodes; aligning and attaching a glass substrate with a plurality of glass through-holes to the insulating protective layer, so that the glass through-holes are aligned with the electrode via-holes respectively, an aperture of each of the glass through-holes being not smaller than an aperture of a corresponding one of the electrode via-holes; forming a plurality of conductive portions, each penetrating through a corresponding one of the glass through-holes and a corresponding one of the electrode via-holes, each of the conductive portions including a first conductive layer and a second conductive layer; the first conductive layer coating an exposed surface of a corresponding one of the driving electrodes, and a second gap being formed between the first conductive layer and an inner wall surface of the corresponding one of the electrode via-holes; the second conductive layer surrounding a side surface of the first conductive layer and filling the second gap and a third gap, and the third gap is formed between the first conductive layer and an inner wall surface of the corresponding one of the glass through-holes; the first conductive layer including an inert conductor with toughness, and the second conductive layer including an elastic conductor; forming a light-emitting component layer on a side of the glass substrate away from the driving substrate, the light-emitting component layer including a plurality of light-emitting units, and an electrode of each of the light-emitting units covering a corresponding one of the conductive portions and being in contact with and electrically connected to the corresponding one of the conductive portions.

In order to solve the problems mentioned above, a third technical solution provided by the present disclosure is a display apparatus. The display apparatus includes a display panel according to any one of embodiments mentioned above.

### BRIEF DESCRIPTION OF THE DRAWINGS

In order to more clearly illustrate the technical solutions in the embodiments of the present disclosure, the drawings needed to be used in the embodiments are briefly introduced below. Obviously, the drawings in the following description are only some embodiments of the present disclosure. For those skilled in the art, other drawings may also be obtained according to these drawings without any creative efforts.

FIG. 1 is a schematic structural view of a display panel according to some embodiments of the present disclosure.

FIG. 2 is a first schematic cross-sectional view of a conductive portion and a driving electrode along a longitudinal direction according to some embodiments of the present disclosure.

FIG. 3 is a schematic top view of the conductive portion and the driving electrode shown in FIG. 2.

FIG. 4 is a second schematic cross-sectional view of a conductive portion and a driving electrode along a longitudinal direction according to some embodiments of the present disclosure.

FIG. 5 is a third schematic cross-sectional view of a conductive portion and a driving electrode along a longitudinal direction according to some embodiments of the present disclosure.

FIG. 6 is a schematic flow chart of a manufacturing method of a display panel according to some embodiments of the present disclosure.

FIG. 7 is a schematic flow chart of an implementation of block S10 shown in FIG. 6.

FIG. 8 is a schematic process chart of the implementation shown in FIG. 7.

FIG. 9 is a schematic flow chart of an implementation of block S30 shown in FIG. 6.

FIG. 10 is a schematic process chart of the implementation shown in FIG. 9.

FIG. 11 is another schematic flow chart of an implementation of block S30 shown in FIG. 6.

FIG. 12 is a schematic process chart of the implementation shown in FIG. 11.

FIG. 13 is a schematic flow chart of an implementation of block S40 shown in FIG. 6.

FIG. 14 is a schematic process chart of the implementation shown in FIG. 13.

FIG. 15 is a schematic structural view of a display apparatus according to some embodiments of the present disclosure.

### DETAILED DESCRIPTION

The solutions in the embodiments of the present disclosure are described in detail below in conjunction with the accompanying drawings.

In the following description, for illustrative rather than limitation, specific details such as specific system structures, interfaces, technologies, etc., are presented to facilitate a thorough understanding of the present disclosure.

The technical solutions in the embodiments of the present disclosure are described clearly and completely below in conjunction with the accompanying drawings in the embodiments of the present disclosure. Obviously, the mentioned embodiments are merely some, not all of the embodiments of the present disclosure. Based on the embodiments in the present disclosure, all other embodiments obtained by those skilled in the art without creative work fall within the scope of protection of the present disclosure.

In the present disclosure, the terms “first”, “second”, and “third” are for descriptive purposes only, and should not be construed as indicating or implying relative importance or implying the number of technical features indicated. Thus, features defining with the terms “first”, “second”, and “third” may explicitly or implicitly include at least one of these features. In the description of the present disclosure, the term “plurality” means at least two, such as two, three, etc., unless otherwise expressly and specifically qualified. All directional indications (such as up, down, left, right, front, back . . . ) in the embodiments of the present disclosure are only used to explain the relative positional relationship, motion states, and etc. between various components in specific postures (as shown in the accompanying drawings). If the specific postures change, the directional indications will change accordingly. In additions, the terms “comprise” and “include”, as well as any variations thereof, are intended to cover non-exclusive inclusions. For example, a process, method, system, product, or device that contains a series of steps or units is not limited to listed steps or units, but may optionally include a step or unit that is not listed, or may optionally include other steps or units that are inherent to the process, method, product, or device.

The term “embodiment” mentioned in the specification means that particular features, structures, or characteristics described in conjunction with the embodiments may be included in at least one embodiment of the present disclosure. This term appearing in various positions in the specification does not necessarily refer to the same embodiment, nor is it an independent or alternative embodiment mutually exclusive with other embodiments. Those skilled in the art explicitly or implicitly understand that the embodiments described in the specification may be combined with other embodiments.

The present disclosure will be illustrated in detail below in conjunction with the accompanying drawings and embodiments.

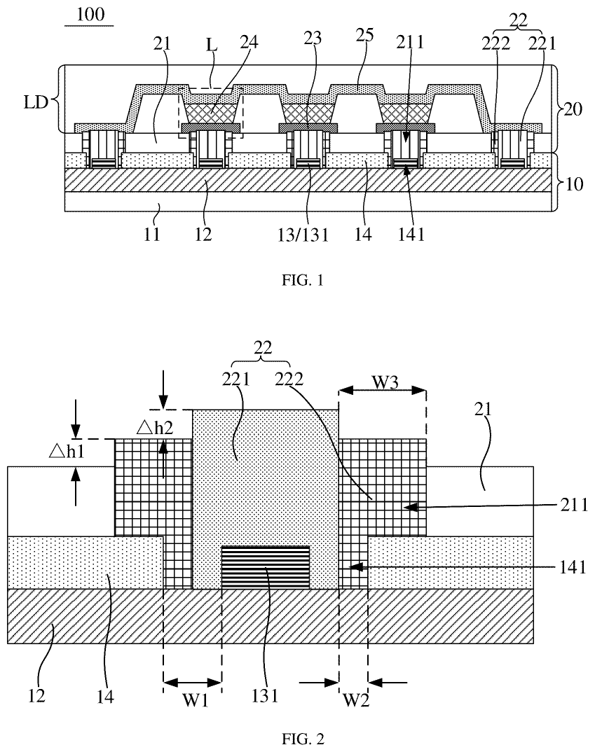

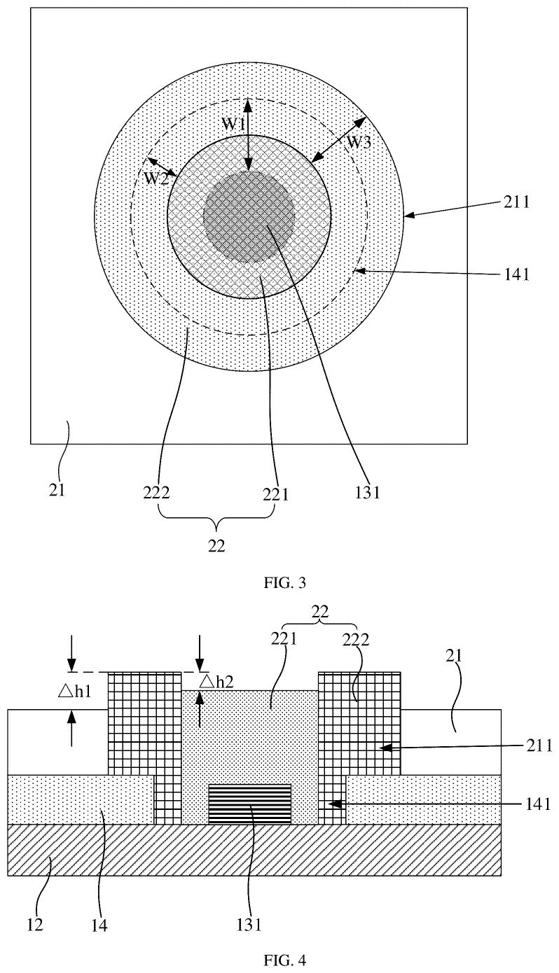

As shown in FIG. 1 to FIG. 3, FIG. 1 is a schematic structural view of a display panel according to some embodiments of the present disclosure, FIG. 2 is a first schematic cross-sectional view of a conductive portion and a driving electrode along a longitudinal direction according to some embodiments of the present disclosure, and FIG. 3 is a schematic top view of the conductive portion and the driving electrode shown in FIG. 2. A display panel 100 is provided in some embodiments, the display panel 100 may include components as follows.

A driving substrate 10 includes a driving circuit layer 12 and a bonding electrode layer 13 and an insulating protective layer 14 arranged on a side of the driving circuit layer 12. The bonding electrode layer 13 includes a plurality of driving electrodes 131 electrically connected to the driving circuit layer 12. The insulating protective layer 14 has a plurality of electrode via-holes 141 defined therein. Each of the electrode via-holes 141 exposes a corresponding one of the driving electrodes 131. A first gap W1 is formed between an inner wall surface of each of the electrode via-holes 141 and the corresponding one of the driving electrodes 131.

A glass substrate 21 is attached to a side of the insulating protective layer 14 away from the driving circuit layer 12, and has a plurality of glass through-holes 211 defined therein and aligned with the electrode via-holes 141 respectively. An aperture of each of the glass through-holes 211 is not smaller than an aperture of a corresponding one of the electrode via-holes 141.

Each of the conductive portions 22 penetrates through a corresponding one of the glass through-holes 211 and a corresponding one of the electrode via-holes 141. Each of the conductive portions 22 includes a first conductive layer 221 and a second conductive layer 222. The first conductive layer 221 coats an exposed surface of a corresponding one of the driving electrodes 131. A second gap W2 is formed between the first conductive layer 221 and an inner wall surface of the corresponding one of the electrode via-holes 141. The second conductive layer 222 surrounds a side of the first conductive layer 221 and fills the second gap W2 and a third gap W3. The third gap W3 is formed between the first conductive layer 221 and an inner wall surface of the corresponding one of the glass through-holes 211. The first conductive layer 221 includes an inert conductor with toughness. The second conductive layer 222 includes an elastic conductor.

A light-emitting component layer LD includes a plurality of light-emitting units L arranged on a side of the glass substrate 21 away from the driving substrate 10. An electrode of each of the light-emitting units L covers a corresponding one of the conductive portions 22 and is in contact with and electrically connected to the corresponding one of the conductive portions 22.

The driving substrate 10 includes a silicon substrate 11, the driving circuit layer 12, the bonding electrode layer 13, and the insulating protective layer 14, which are sequentially stacked. In some embodiments, the silicon substrate 11 may be configured as a single-crystal silicon substrate.

The driving circuit layer 12 includes a plurality of pixel driving circuits (not shown). Each of the pixel driving circuits includes a semiconductor driving component. In some embodiments, a CMOS component may be used as the semiconductor driving component to manufacture one pixel driving circuit for driving a corresponding light-emitting unit L to emit light.

As shown in FIG. 1, the bonding electrode layer 13 includes the driving electrodes 131. Each of the driving electrodes 131 is electrically connected to a corresponding pixel driving circuit, so that a driving signal is transmitted to the driving electrode 131 by a corresponding pixel driving circuit, and then transmitted to the corresponding light-emitting unit L through a corresponding conductive portion 22, thereby driving the corresponding light-emitting unit L to emit light. The bonding electrode layer 13 includes a plurality of first driving electrodes 131, each being electrically connected to a corresponding pixel driving circuit, and a plurality of second driving electrodes 131, each being electrically connected to a power supply wire (not shown). In some embodiments, the power supply wire is usually arranged in a frame region of the driving substrate 10. Each of the first driving electrodes 131 is electrically coupled with a first electrode 23 of a corresponding light-emitting unit L through a corresponding conductive portion 22. Each of the second driving electrodes 131 is electrically coupled with a second electrode 25 of the corresponding light-emitting unit L through a corresponding conductive portion 22. In this way, a light-emitting loop is formed and the light-emitting unit L is driven to emit light.

As shown in FIG. 2 and FIG. 3, the insulating protective layer 14 is arranged on a side of the driving circuit layer 12 away from the silicon substrate 11, and has the electrode via-holes 141 defined therein. Each of the driving electrodes 131 is located in a corresponding electrode via-hole 141. A side surface of the driving electrode 131 away from the driving circuit layer 12 and sidewall surfaces of the driving electrode 131 are exposed in the corresponding electrode via-hole 141, so that the first gap W1 is defined between each of the sidewall surfaces of the driving electrode 131 and the inner wall surface of the corresponding electrode via-hole 141. It can be understood that a size on a cross-section of the electrode via-hole 141 is greater than a size on the cross-section of the driving electrode 131, so that the inner wall surface of the electrode via-hole 141 is not in contact with the driving electrode 131 and has a certain gap between thereof. In this way, a space is reserved for the filling of the conductive portion 22, and partial of the conductive portion 22 may be filled to the first gap W1 to coat the driving electrode 131, thereby improving the connection stability between the conductive portion 22 and the driving electrode 131. The insulating protective layer 14 may include an inorganic insulating layer and/or an organic insulating layer. In some embodiments, the insulating protective layer 14 may be configured as an inorganic insulating layer. A material of the inorganic insulating layer may be an inorganic insulating material such as silicon dioxide (SiO₂), silicon nitride (Si₃N₄), silicon oxynitride (SiOₓN_{y}), or aluminum oxide (Al₂O₃).

As shown in FIG. 1 and FIG. 2, a light-emitting substrate 20 includes the glass substrate 21, the conductive portions 22, and the light-emitting component layer LD. The glass substrate 21 is defined with the glass through-holes 211. The distribution and arrangement of the glass through-holes 211 are matched with the distribution and arrangement of the electrode via-holes 141, so that in a case where the glass substrate 21 is aligned and attached to the insulating protective layer 14, each glass through-hole 211 is aligned with the corresponding electrode via-hole 141, enabling the glass through-hole 211 and the aligned electrode via-hole 141 to form a two-stage hole. The aperture of the glass through-hole 211 is not smaller than the aperture of the electrode via-hole 141, so that the glass substrate 21 will not block the electrode via-hole 141 in a direction perpendicular to the driving substrate 10. This is beneficial for the conductive portion 22 to be filled into the first gap W1, and help avoid a problem of a hollow formed between the driving electrode 131 and the inner wall surface of the electrode via-hole 141, which could affect the signal transmission.

The conductive portion 22 penetrates through the glass through-hole 211 and the electrode via-hole 141. That is, the conductive portion 22 penetrates through the two-stage hole formed by the glass through-hole 211 and the electrode via-hole 141. The conductive portion 22 includes the first conductive layer 221 and the second conductive layer 222, and the first conductive layer 221 coats an exposed surface of the driving electrode 131. That is, the first conductive layer 221 coats an exposed upper surface and the exposed sidewall surface of the driving electrode 131, thereby increasing the contact area between the first conductive layer 221 and the driving electrode 131, and effectively improving the connection stability between the first conductive layer 221 and the driving electrode 131. The first conductive layer 221 includes the inert conductor with toughness, The inertness of the first conductive layer 221 may ensure the chemical stability and conductive effectiveness of the first conductive layer 221. The toughness of the first conductive layer 221 may make the first conductive layer 221 have supporting stability, so as to avoid the first conductive layer 221 from being damaged or broken under an action of external force. In this way, the support stability and the effectiveness of signal transmission of the conductive portion 22 are ensured. The second gap W2 is formed between the first conductive layer 221 and the inner wall surface of the electrode via-hole 141. That is, a thickness of the first conductive layer 221 coating the sidewall surface of the driving electrode 131 is smaller than a width of the first gap W1, so that the second gap W2 is formed between the first conductive layer 221 and the inner wall surface of the electrode via-hole 141. The second conductive layer 222 surrounds the side surface of the first conductive layer 221 and fills the second gap W2 and the third gap W3. The third gap W3 is formed between the first conductive layer 221 and the inner wall surface of the glass through-hole 211. That is, the second conductive layer 222 surrounds and coats on a sidewall surface of the first conductive layer 221, and fills a remaining gap of the two-stage hole. In this way, an inner sidewall surface of the second conductive layer 222 is in contact with the side surface of the first conductive layer 221, and an outer sidewall surface of the second conductive layer 222 is in contact with the inner wall surface of the electrode via-hole 141 and the inner wall surface of the glass through-hole 211 respectively, so as to further improve the connection stability of the conductive portion 22. The second conductive layer 222 includes the elastic conductor, enabling the second conductive layer 222 to be used as a buffer layer for the first conductive layer 221. In this way, when a relative positional shift occurs between the driving substrate 10 and the light-emitting substrate 20, causing the conductive portion 22 to be pulled by an external force, the second conductive layer 222 may act as a buffer for the first conductive layer 221 to protect the first conductive layer 221. This can effectively reduce the occurrence of damage or fracture of the first conductive layer 221 when the first conductive layer 221 is pulled by the external force, effectively improving the connection stability of the conductive portion 22. As a result, the effectiveness and integrity of signal transmission of the conductive portion 22 are ensured.

In some embodiments, the glass substrate 21 is arranged between the driving substrate 10 and the light-emitting component layer LD. That is, the light-emitting component layer LD needs to be fabricated and formed on the glass substrate 21. In this way, in a process of manufacturing the light-emitting component layer LD, the glass substrate 21 may protect the driving circuit layer 12 of the driving substrate 10, avoiding damage to the driving circuit layer 12 when the light-emitting component layer LD is directly manufactured on the driving substrate 10, and improving the product yield.

A material of the first conductive layer 221 includes a metal or metal oxide. For example, the material may include one or more of inert conductor materials such as silver (Ag), gold (Au), copper (Cu), copper-silver alloy (Cu—Ag), nickel-iron alloy (Ni₂Fe), a composite material of nickel ferrite and nickel oxide (NiFe₂O₄+NiO), nickel ferrite (NiXFe₃—XO₄), a composite material of zinc oxide and zinc ferrite (ZnO+ZnFe₂O₄), etc., which can be set according to actual requirements.

A material of the second conductive layer 222 include a polymer conductive nanomaterial or other conductive materials with elasticity. The material of the second conductive layer 222 includes a matrix material and a conductive filler. The matrix material makes the second conductive layer 222 elastic, and the conductive filler makes the second conductive layer 222 with good electrical conductivity. The matrix material includes one or more of polymer materials such as polydimethylsiloxane (PDMS), polyethylene terephthalate (PET), polyurethane (PU), styrene-butadiene-styrene block copolymer (SBS), etc. The conductive filler may include one or more of conductive materials such as gallium-indium tin alloy (Galinstan), carbon black, a carbon nanotube, graphene, metal powders, a metal nanowire, a metal nanosheet, etc. In some embodiments, for example, a liquid metal gallium-indium tin alloy (Galinstan) that is easy to deform and has good conductivity may be used as the conductive filler, and polydimethylsiloxane (PDMS) is used as the matrix material. These two materials are compounded to prepare an elastic second conductive layer 222, so that the second conductive layer 222 not only has good electrical conductivity (e.g., the electrical conductivity may reach 1.34×10³ Scm⁻¹) and a large tensile limit (e.g., the second conductive may be stretched to 216.86% of its original length). Moreover, the second conductive layer 222 has more stable mechanical properties. When the second conductive layer 222 is stretched to 200% of its original length, a relative change rate of a resistance of the second conductive layer 222 is 4.305%. In this way, the second conductive layer 222 not only has better electrical conductivity and mechanical stability, enhancing the ability of the conductive portion 22 to resist external forces, but also guarantees the stability of signal transmission. Meanwhile, the second conductive layer 222 may provide a better protective for the first conductive layer 221.

As shown in FIG. 2, a width of the first gap W1 between the driving electrode 131 and the inner wall surface of the electrode via-hole 141 is 0.8 μm to 1.2 μm. A width of the second gap W2 between the sidewall surface of the first conductive layer 221 away from the driving electrode 131 and the inner wall surface of the electrode via-hole 141 is 0.4 μm to 0.6 μm. It can be understood that a first coating thickness of the first conductive layer 221 on the sidewall surface of the driving electrode 131 is 0.4 μm to 0.6 μm. For example, the first coating thickness may be 0.4 μm, 0.5 μm, or 0.6 μm. A second coating thickness of the second conductive layer 222 on the sidewall surface of the first conductive layer 221 is 0.4 μm to 0.8 μm. For example, the second coating thickness may be 0.4 μm, 0.5 μm, 0.6 μm, 0.7 μm, or 0.8 μm. The width values of the first gap W1 and the second gap W2 may be specifically set according to the design requirements of the specific structural stability and the effectiveness of signal transmission of the conductive portion 22. In some embodiments, the first gap W1 is 1.0 μm, and the second gap W2 is 0.5 μm. In this way, the support stability of the first conductive layer 221, the protective effect of the second conductive layer 222 for the first conductive layer 221, and the effectiveness and integrity of signal transmission of the conductive portion 22 are ensured.

In some embodiments, the glass through-hole 211 is coaxially arranged with the electrode via-hole 141, and the aperture of the glass through-hole 211 is greater than the aperture of the electrode via-hole 141. That is, the insulating protective layer 14 and the glass substrate 21 form a stepped shape at the junction therebetween, so that the second conductive layer 222 has an annular contact surface with a certain width with the insulating protective layer 14 around a periphery of an upper port of the electrode via-hole 141 close to the glass substrate 21, increasing a contact area between the second conductive layer 222 and the insulating protective layer 14. The step formed at the junction between the insulating protective layer 14 and the glass substrate 21 facilitates the adhesion of the second conductive layer 222, further improving the connection stability between the second conductive layer 222 and the driving substrate 10. Half of a difference between the aperture of the glass through-hole 211 and the aperture of the electrode via-hole 141 is 0.4 μm to 0.6 μm. That is, a surface of a part of the insulating protective layer 14 exposed by the glass through-hole 211 on a side away from the driving circuit layer 12 is annular. A width of the annular is 0.4 μm to 0.6 μm, which may be 0.4 μm, 0.5 μm, or 0.6 μm, and may be set specifically according to the actual design requirements.

In the embodiments of the present disclosure, heights of the glass substrate 21, the first conductive layer 221, and the second conductive layer 222 away from a side of the driving substrate 10 are different, and both a height difference between the second conductive layer 222 and the first conductive layer 221 and a height difference between the second conductive layer 222 and the glass substrate 21 are in a range of 800 angstroms to 1200 angstroms (Å). The heights of the glass substrate 21, the first conductive layer 221, and the second conductive layer 222 away from the side of the driving substrate 10 are different, enabling a contact area between an electrode of a corresponding light-emitting unit L and the conductive portion 22 to be increased. In this way, the stability of the connection structure between the conductive portion 22 and the electrode of the corresponding light-emitting unit L is improved, and the resistance is reduced for reducing a signal voltage drop and improving the integrity of signal transmission.

In some embodiments, heights of the glass substrate 21, the second conductive layer 222, and the first conductive layer 221 away from the side of the driving substrate 10 are successively increased to form a stepped shape. In this way, the contact area between the electrode of the light-emitting unit L and the corresponding conductive portion 22 is increased, and the stability of the connection structure between the conductive portion 22 and the first electrode 23 or the second electrode 25 is improved. A second height difference Δh2 between the first conductive layer 221 and the second conductive layer 222 may be 1000 Å. A first height difference Δh1 between the second conductive layer 222 and the glass substrate 21 may also be 1000 Å. Alternatively, the first height difference and the second height difference may be different, which may be set specifically according to actual requirements, as long as they are within a range of 800 Å to 1200 Å, so as to avoid a situation where the electrode are not easy to climb and deposit due to an excessively large height difference.

As shown in FIG. 4, FIG. 4 is a second schematic cross-sectional view of a conductive portion and a driving electrode along a longitudinal direction according to some embodiments of the present disclosure. In some embodiments, heights of the glass substrate 21, the first conductive layer 221, and the second conductive layer 222 away from the side of the driving substrate 10 are successively increased. That is, the second conductive layer 222 is the highest, and the heights of the first conductive layer 221 and the glass substrate 21 located on both sides of the second conductive layer 222 are lower than the height of the second conductive layer 222. In this way, a step is formed between the glass substrate 21 and the second conductive layer 222, another step is formed between the second conductive layer 222 and the first conductive layer 221, and the height of the first conductive layer 221 is higher than the height of the glass substrate 21. That is, both the first conductive layer 221 and the second conductive layer 222 are higher than the glass substrate 21, thereby increasing the contact area between the electrode of the light-emitting unit L and the corresponding conductive portion 22, and improving the stability of the connection structure between the conductive portion 22 and the first electrode 23 or the second electrode 25. The second height difference Δh2 between the second conductive layer 222 and the first conductive layer 221 may be 1000 Å. A height difference between the first conductive layer 221 and the glass substrate 21 may be 800 Å. Alternatively, the second height difference and the height difference may be other values, which may be set specifically according to actual requirements, as long as they are within a range of 800 Å to 1200 Å, so as to avoid a situation where the electrode are not easy to climb and deposit due to an excessively large height difference.

In other embodiments, heights of the first conductive layer 221 and the glass substrate 21 away from the side of the driving substrate 10 are the same. The second conductive layer 222 is higher than the first conductive layer 221, and the second height difference Δh2 between the second conductive layer 222 and the first conductive layer 221 is between 800 Å to 1200 Å. The height of the first conductive layer 221, the height of the second conductive layer 222, and the height of the glass substrate 21 may be set according to actual requirements, so as to increase the contact area between the electrode of the corresponding light-emitting unit L and the conductive portion 22, thereby improving the stability of the connection structure between the conductive portion 22 and the electrode of the corresponding light-emitting unit L, and reducing the resistance to reduce a signal voltage drop and improve the integrity of signal transmission.

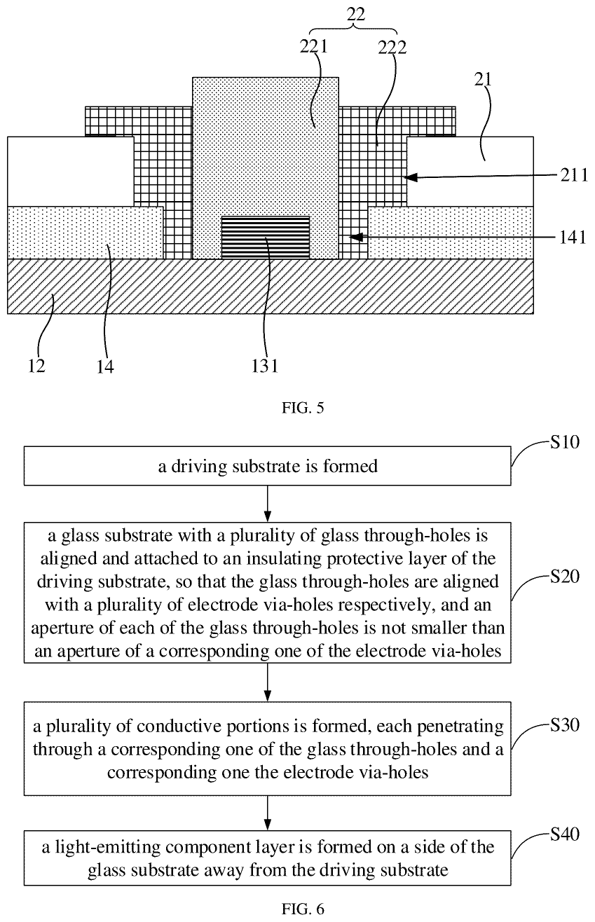

As shown in FIG. 5, FIG. 5 is a third schematic cross-sectional view of a conductive portion and a driving electrode along a longitudinal direction according to some embodiments of the present disclosure. In some embodiments, the glass through-hole 211 is coaxially arranged with the corresponding electrode via-hole 141. The aperture of the glass through-hole 211 is greater than the aperture of the corresponding electrode via-hole 141. The driving electrode 131 is centered and arranged within an orthographic projection of the electrode via-hole 141 projected on the driving circuit layer 12. In this way, current distribution of driving signal is more evenly balanced, so as to reduce the voltage drop.

Further, in some embodiments, the second conductive layer 222 may extend out of the glass through-hole 211 along a direction parallel to the glass substrate 21 and partially attach to a side of the glass substrate 21 away from the driving substrate 10. In this way, the contact area between the second conductive layer 222 and the glass substrate 21 is increased, improving the connection reliability between the conductive portion 22 and the glass substrate 21. An extension range of the second conductive layer 222 extending out of the glass through-hole 211 along the direction parallel to the glass substrate 21 does not exceed a range of the electrode of the corresponding light-emitting unit L, so as to avoid the problem of signal serial connection.

Further, in some embodiments, if the height of the first conductive layer 221 away from the side of the driving substrate 10 is higher than the height of the second conductive layer 222 away from the side of the driving substrate 10, the first conductive layer 221 may extend to the second conductive layer 222 along the direction parallel to the glass substrate 21. In this way, the contact area between the first conductive layer 221 and the second conductive layer 222 is increased, further improving the connection reliability between the first conductive layer 221 and the second conductive layer 222. Meanwhile, the protection effect of the first conductive layer 221 for the second conductive layer 222 is improved.

As shown in FIG. 1, in some embodiments, the light-emitting component layer LD includes a first electrode layer, a plurality of light-emitting layers 24, and a second electrode layer are sequentially stacked on the glass substrate 21. The first electrode layer includes a plurality of first electrodes 23, each covering a corresponding conductive portion 22. Each of the light-emitting layers 24 is arranged on a side of a corresponding first electrode 23 away from the glass substrate 21 and is in contact with the corresponding first electrode 23. The second electrode layer includes a second electrode 25 covering the light-emitting layers 24 in a whole layer manner, so as to form the light-emitting units L. The second electrode 25 extends to an edge region of the glass substrate 21 and covers the conductive portions 22 within the edge region to be in electrical contact with the conductive portions 22. In this way, the second electrode 25 is electrically coupled with the driving substrate 10 through the conductive portions 22. The first electrodes 23 may be anodes and the second electrode 25 may be a cathode. In other embodiments, the first electrodes 23 may be cathodes and the second electrode 25 may be an anode.

As shown in FIG. 6, FIG. 6 is a schematic flow chart of a manufacturing method of a display panel according to some embodiments of the present disclosure. A manufacturing method of a display panel is provided by some embodiments, configured to manufacture the display panel 100 as described in the above embodiments. The manufacturing method may include operations executed by the following blocks.

At block S10, a driving substrate 10 is formed.

At block S20, a glass substrate 21 with a plurality of glass through-holes 211 is aligned and attached to an insulating protective layer 14 of the driving substrate 10, so that the glass through-holes 211 are aligned with a plurality of electrode via-holes 141 respectively. An aperture of each of the glass through-holes 211 is not smaller than an aperture of a corresponding one of the electrode via-holes 141.

At block S30, a plurality of conductive portions 22 is formed, each penetrating through a corresponding one of the glass through-holes 211 and a corresponding one of the electrode via-holes 141.

At block S40, a light-emitting component layer LD is formed on a side of the glass substrate 21 away from the driving substrate 10.

The structure and function of the driving substrate 10 fabricated through an operation executed by the block S10 are identical or similar to the structure and function of the driving substrate 10 provided in the above embodiments, and the same technical effect can be realized, specifically refer to the relevant introduction above, and will not be repeated herein. The driving substrate 10 includes a silicon substrate 11, the driving circuit layer 12, the bonding electrode layer 13, and the insulating protective layer 14, which are sequentially stacked. The bonding electrode layer 13 includes a plurality of driving electrodes 131 electrically connected to the driving circuit layer 12. The insulating protective layer 14 has a plurality of electrode via-holes 141 defined therein. Each of the electrode via-holes 141 exposes a corresponding driving electrode 131. A first gap W1 is formed between an inner wall surface of the electrode via-hole 141 and the corresponding driving electrode 131.

At block S20, the glass substrate 21 is defined with a plurality of glass through-holes 211. Laser irradiation may be carried out at corresponding positions (e.g., positions where signal connection is required) of the glass substrate 21 to form corresponding modified regions on the glass substrate 21 in bottom regions of the first electrodes 23 and bottom regions of the second electrodes 25, and then the modified regions are etched with an etching solution to form the glass through-holes 211.

The conductive portions 22, which are fabricated through an operation executed by the block S30, each penetrates through a corresponding one of the glass through-holes 211 and a corresponding one of the electrode via-holes 141. Each of the conductive portions 22 includes a first conductive layer 221 and a second conductive layer 222. The first conductive layer 221 coats an exposed surface of a corresponding one of the driving electrodes 131. A second gap W2 is formed between the first conductive layer 221 and an inner wall surface of the corresponding one of the electrode via-holes 141. The second conductive layer 222 surrounds a side of the first conductive layer 221 and fills the second gap W2 and a third gap W3. The third gap W3 is formed between the first conductive layer 221 and an inner wall surface of the corresponding one of the glass through-holes 211. The first conductive layer 221 includes an inert conductor with toughness. The second conductive layer 222 includes an elastic conductor.

The light-emitting component layer LD, fabricated through an operation executed by the block S40, includes a plurality of light-emitting units L arranged on a side of the glass substrate 21 away from the driving substrate 10. An electrode of one of the light-emitting units L covers a corresponding one of the conductive portions 22 and is in contact with and electrically connected to the corresponding one of the conductive portions 22.

The display panel 100, manufactured by some embodiments, includes the driving substrate 10, and the glass substrate 21 and the light-emitting component layer LD sequentially stacked on the driving substrate 10. The glass substrate 21 is arranged between the driving substrate 10 and the light-emitting component layer LD, and the light-emitting component layer LD is formed on the glass substrate 21. In this way, in a process of manufacturing the light-emitting component layer LD, the glass substrate 21 may protect the driving circuit layer 12 of the driving substrate 10, avoiding damage to the driving circuit layer 12 when the light-emitting component layer LD is directly manufactured on the driving substrate 10, and improving the product yield. By forming the glass through-holes 211 in the glass substrate 21 and arranging the conductive portions 22 within the glass through-holes 211 respectively, the light-emitting units L are in signal connection with the driving substrate 10 through the conductive portions 22, so as to display corresponding images.

Further, the first gap W1 is formed between the inner wall surface of the driving electrode 131 and the electrode via-hole 141, and the first conductive layer 221 of the conductive portion 22 coats an exposed surface of the driving electrode 131, thereby increasing the contact area between the first conductive layer 221 and the driving electrode 131, and improving the connection stability. Meanwhile, the support stability and the effectiveness of signal transmission of the first conductive layer 221 are improved by making the first conductive layer 221 including an flexible inert conductor. The second gap W2 is formed between the first conductive layer 221 and the inner wall surface of the electrode via-hole 141, making the second conductive layer 222 of the conductive portion 22 to surround the side surface of the first conductive layer 221, and to fill the second gap W2 and the third gap W3, which is formed between the first conductive layer 221 and the inner wall surface of the glass through-hole 211, further improving the structural stability of the conductive portion 22. The second conductive layer 222 includes an elastic conductor. When the conductive portion 22 is subjected to an external force, the second conductive layer 222 may be used as a buffer layer to provide a buffering effect for the first conductive layer 221, so as to avoid the fracture or damage to the first conductive layer 221 caused by the external force. Even if the first conductive layer 221 is fractured, and the second conductive layer 222 is not easy to be damaged and fractured because of its toughness, so that the conductive portion 22 may still maintain the stability of signal transmission.

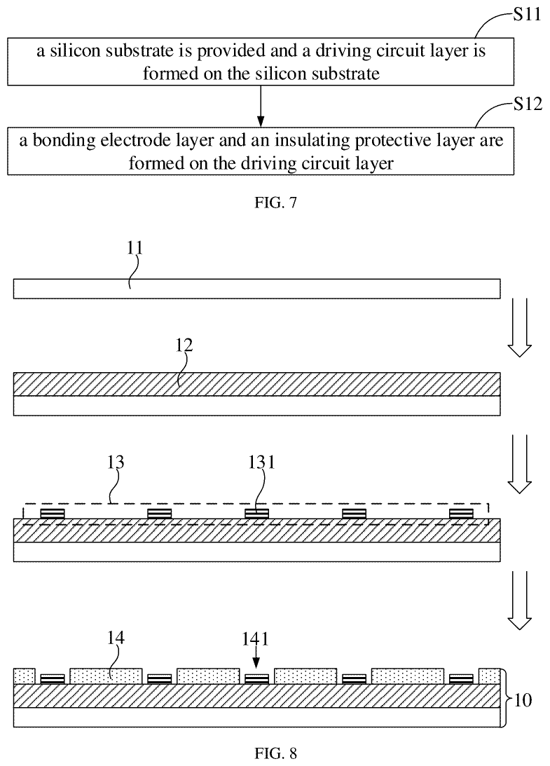

As shown in FIG. 7 and FIG. 8, FIG. 7 is a schematic flow chart of an implementation of block S10 shown in FIG. 6, and FIG. 8 is a schematic process chart of the implementation shown in FIG. 7. The block S10 for forming the driving substrate 10 may include operations as follows.

At block S11, a silicon substrate 11 is provided and a driving circuit layer 12 is formed on the silicon substrate 11.

At block S12, a bonding electrode layer 13 and an insulating protective layer 14 are formed on the driving circuit layer 12.

The silicon substrate 11 may be a single-crystal silicon substrate. The driving circuit layer 12 includes a plurality of pixel driving circuits for driving the light-emitting units L to emit light. The bonding electrode layer 13 includes a plurality of driving electrodes 131. The structure and function of the driving electrodes 131 and the insulating protective layer 14 are identical or similar to the structure and function of the driving electrodes 131 and the insulating protective layer 14 involved in the above embodiments, and the same technical effect may be realized, specifically refer to the relevant introduction above, and will not be repeated herein.

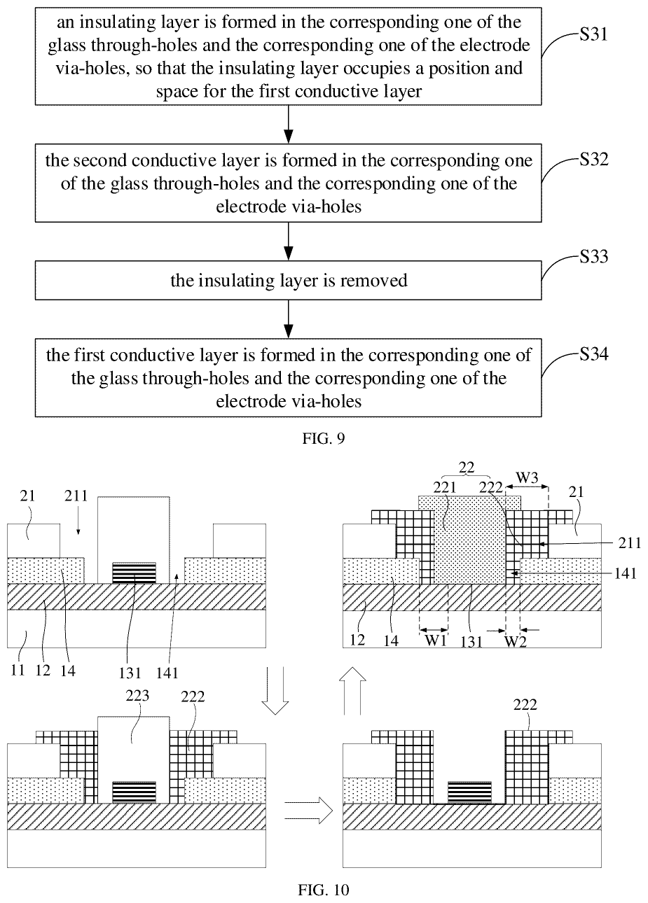

As shown in FIG. 9 and FIG. 10, FIG. 9 is a schematic flow chart of an implementation of block S30 shown in FIG. 6, and FIG. 10 is a schematic process chart of the implementation shown in FIG. 9. In some embodiments, the block S30 for forming the conductive portions 22 may include operations as follows.

At block S31, an insulating layer 223 is formed in the corresponding one of the glass through-holes 211 and the corresponding one of the electrode via-holes 141, so that the insulating layer 223 occupies a position and space for the first conductive layer 221.

At block S32, the second conductive layer 222 is formed in the corresponding one of the glass through-holes 211 and the corresponding one of the electrode via-holes 141.

At block S33, the insulating layer 223 is removed.

At block S34, the first conductive layer 221 is formed in the corresponding one of the glass through-holes 211 and the corresponding one of the electrode via-holes 141.

In some embodiments, after completing the block S20, the insulating layer 223 is first formed in the position and space for the first conductive layer 221 to fill the space for the first conductive layer 221. Then the material of the second conductive layer 222 may be filled in a gap between the insulating layer 223 and an inner wall surface of a two-stage hole (i.e., a two-stage hole formed by the glass through-hole 211 and the corresponding electrode via-hole 141) through patterning processes such as inkjet printing or 3D printing, so as to form an elastic second conductive layer 222. After the second conductive layer 222 is fabricated, the insulating layer 223 may be removed through an etching process to release the space for the first conductive layer 221. Then the material of the first conductive layer 221 is filled in a space enclosed by the second conductive layer 222 to cover the exposed surface of the driving electrode 131 and is in contact with the second conductive layer 222.

The insulating layer 223 may be a single layer structure or a multi-layer stacked film layer. When the insulating layer 223 is a single-layer structure, the insulating layer 223 may be an inorganic insulating layer. When the insulating layer 223 is a multi-layer stacked structure, the insulating layer 223 may be, for example, a sandwich film structure of inorganic insulating layer+organic insulating layer+inorganic insulating layer. The organic insulating layer is sandwiched between two inorganic insulating layers.

In some embodiments, the second conductive layer 222 is first fabricated, and then the first conductive layer 221 is fabricated. In this way, the height of the second conductive layer 222 may be higher than the height of the glass substrate 21, and the second conductive layer 222 may extend out of the glass through-hole 211 to a part of an upper surface of the glass substrate 21. The height of the first conductive layer 221 may be higher than the height of the second conductive layer 222, and an edge of the first conductive layer 221 may extend to a part of an upper surface of the second conductive layer 222. The connection reliability and the effectiveness and integrity of signal transmission of the conductive portion 22 are further improved.

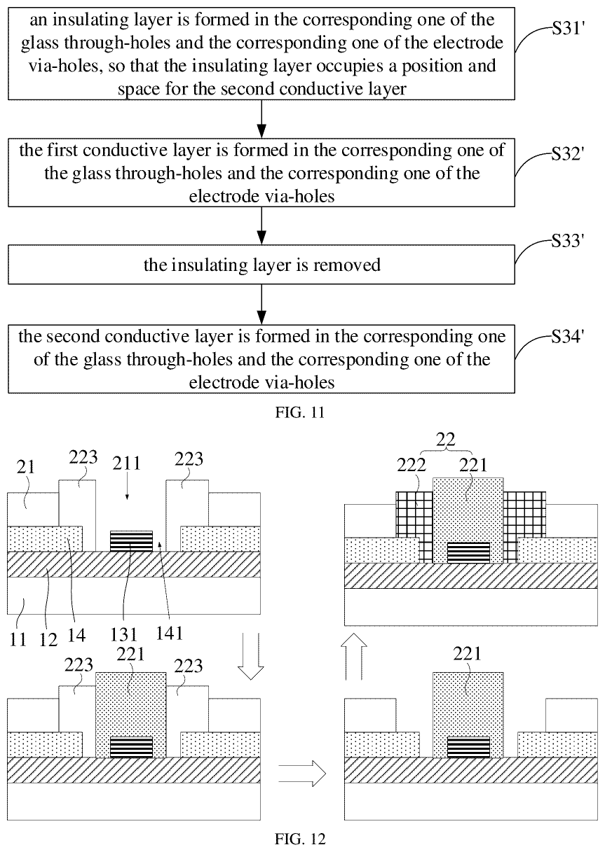

As shown in FIG. 11 and FIG. 12, FIG. 11 is another schematic flow chart of an implementation of block S30 shown in FIG. 6, and FIG. 12 is a schematic process chart of the implementation shown in FIG. 11. In some embodiments, another method for forming the conductive portions 22 is provided. The block S30 for forming the conductive portion 22 may include operations as follows.

At block S31′, an insulating layer 223 is formed in the corresponding one of the glass through-holes 211 and the corresponding one of the electrode via-holes 141, so that the insulating layer 223 occupies a position and space for the second conductive layer 222.

At block S32′, the first conductive layer 221 is formed in the corresponding one of the glass through-holes 211 and the corresponding one of the electrode via-holes 141.

At block S33′, the insulating layer 223 is removed.

At block S34′, the second conductive layer 222 is formed in the corresponding one of the glass through-holes 211 and the corresponding one of the electrode via-holes 141.

In some embodiments, after completing the block S20, the insulating layer 223 is first formed at the position and space for the second conductive layer 222 to fill the space for the second conductive layer 222. Then the material of the first conductive layer 221 may be filled in a space enclosed by the insulating layer 223 through a metal deposition process, so that the first conductive layer 221 formed by deposition may coat the exposed surface of the driving electrode 131. After the first conductive layer 221 is fabricated, the insulating layer 223 may be removed through an etching process to release the space for the second conductive layer 222. Then the material of the second conductive layer 222 is filled in a gap between the first conductive layer 221 and the inner wall surface of the two-stage hole through processes such as inkjet printing or 3D printing, so as to form the elastic second conductive layer 222.

In the embodiments, the manufacturing method of first forming the first conductive layer 221 and then forming the second conductive layer 222 makes it unnecessary to etch the insulating layer 223 on the exposed surface of the driving electrode 131, which may avoid damaging the driving electrode 131 during the etching process.

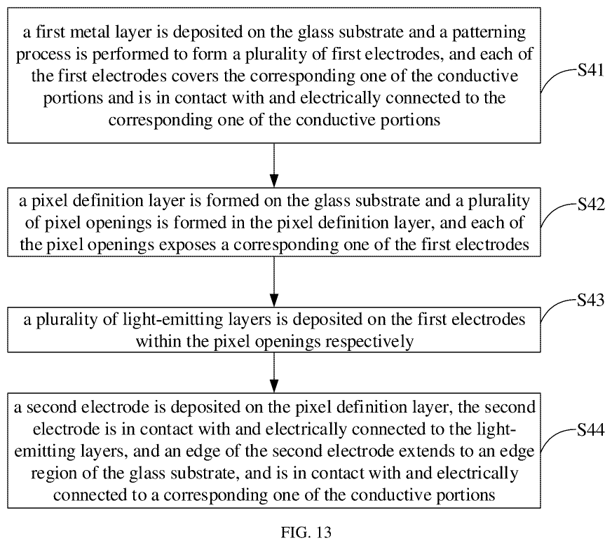

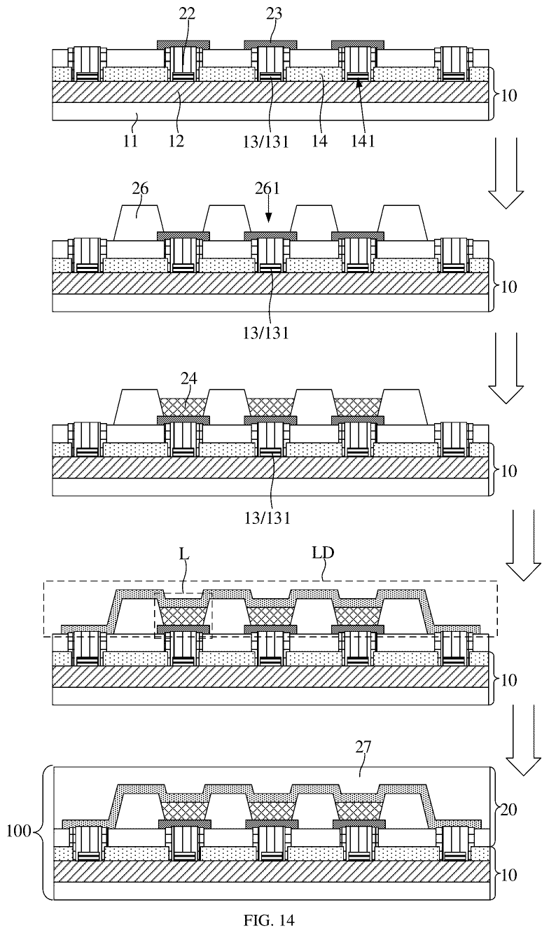

As shown in FIG. 13 and FIG. 14, FIG. 13 is a schematic flow chart of an implementation of block S40 shown in FIG. 6, and FIG. 14 is a schematic process chart of the implementation shown in FIG. 13. In some embodiments, the block S40 for forming the light-emitting component layer LD may include operations as follows.

At block S41, a first metal layer is deposited on the glass substrate 21 and a patterning process is performed to form a plurality of first electrodes 23. Each of the first electrodes 23 covers the corresponding one of the conductive portions 22 and is in contact with and electrically connected to the corresponding one of the conductive portions 22.

At block S42, a pixel definition layer 26 is formed on the glass substrate 21 and a plurality of pixel openings 261 is formed in the pixel definition layer 26. Each of the pixel openings 261 exposes a corresponding one of the first electrodes 23.

At block S43, a plurality of light-emitting layers 24 is deposited on the first electrodes 23 within the pixel openings 261 respectively.

At block S44, a second electrode 25 is deposited on the pixel definition layer 26. The second electrode 25 is in contact with and electrically connected to the light-emitting layers 24. An edge of the second electrode 25 extends to an edge region of the glass substrate 21, and is in contact with and electrically connected to a corresponding one of the conductive portions 22.

Through block S41, the first electrodes 23 covering and contacting the conductive portions 22 are formed. The first electrodes 23 may be anodes of the light-emitting units L. Through block S42, the pixel openings 261 are defined to form accommodating spaces for the light-emitting units L, so as to separate the light-emitting units L. The pixel definition layer 26 may be formed by a photolithography process. At block S43, a mask may be used for the evaporation of the light-emitting layers 24 to form the light-emitting layers 24 of a single color, or to form a first light-emitting layer, a second light-emitting layer, and a third light-emitting layer of different colors. The emission colors of the first light-emitting layer, the second light-emitting layer, and the third light-emitting layer are red, blue, and green respectively, so as to achieve color display. At block S44, the second electrode 25 is formed by full-surface evaporation deposition, and the second electrode 25 is brought into contact and electrical connection with the light-emitting layers 24 to form the light-emitting units L. The edge of the second electrode 25 extends to the edge region of the glass substrate 21 and is in contact with and electrically connected to the corresponding conductive portions 22, so that the second electrode 25 is electrically coupled with the driving substrate 10 through the conductive portions 22 to realize the lighting circuits of the light-emitting units L.

Alternatively, in other embodiments, a plurality of conductive isolation structures (not shown) may be formed on the pixel definition layer 26, so that each of the conductive isolation structures encloses each pixel opening 261. The conductive isolation structure includes a conductive enclosure structure located on the pixel definition layer 26 and a top structure located on the conductive enclosure structure. The top structure covers the conductive enclosure structure, and extends beyond the conductive enclosure structure along the direction parallel to the glass substrate 21 to form an eaves structure. The conductive enclosure structure may replace the mask for evaporation of the light-emitting layers 24 and the second electrode 25, and the cathode electrodes are in contact with the conductive enclosure structure to form a whole surface network connection between the cathode electrodes.

In some embodiments, block S40 may also include operation as follows.

At block S45, an encapsulating layer 27 is formed on a side of the second electrode 25 away from the glass substrate 21 to encapsulate the light-emitting units L.

The encapsulating layer 27 may be specifically a multi-layer stacked film structure of an organic encapsulating layer and an inorganic encapsulating layer to ensure the effectiveness of encapsulation, thereby isolating external water and oxygen and preventing the failure of the light-emitting units L caused by the invasion of water and oxygen.

The display panel 100 is manufactured by the manufacturing method provided in the above embodiments, and the structure and function of the display panel 100 are identical or similar to the structure and function of the display panel 100 described in the above embodiments, and the same technical effect can be realized, specifically refer to the relevant introduction above.

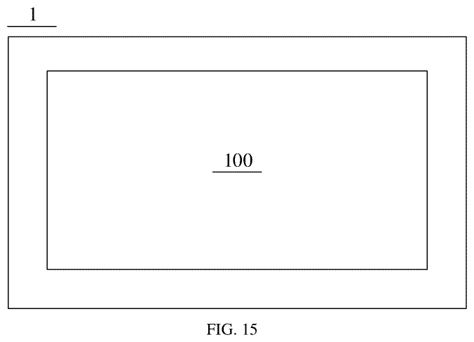

As shown in FIG. 15, FIG. 15 is a schematic structural view of a display apparatus according to some embodiments of the present disclosure. In some embodiments, a display device 1 is provided. The display device 1 includes the display panel 100 described in the above embodiments. The display panel 100 may improve the connection reliability and the effectiveness and integrity of signal transmission between the light-emitting substrate 20 and the driving substrate 10, and may improve the product yield.

The foregoing is only embodiments of the present disclosure, and does not limit the scope of the patent of the present disclosure. Any equivalent structural or equivalent process modifications made by using the contents of the description and drawings of the present disclosure, or directly or indirectly applied to other related technical fields, are similarly fall within the scope of patent protection of the present disclosure.

1. A display panel, comprising:
a driving substrate, comprising:
a driving circuit layer;
a bonding electrode layer and an insulating protective layer, arranged on a side of the driving circuit layer, wherein the bonding electrode layer comprises a plurality of driving electrodes electrically connected to the driving circuit layer; the insulating protective layer has a plurality of electrode via-holes defined therein, each of the electrode via-holes exposes a corresponding one of the driving electrodes, and a first gap is formed between an inner wall surface of each of the electrode via-holes and the corresponding one of the driving electrodes;
a glass substrate, attached to a side of the insulating protective layer away from the driving circuit layer, wherein the glass substrate has a plurality of glass through-holes defined therein and aligned with the electrode via-holes respectively, and an aperture of each of the glass through-holes is not smaller than an aperture of a corresponding one of the electrode via-holes;
a plurality of conductive portions, each penetrating through a corresponding one of the glass through-holes and a corresponding one of the electrode via-holes, and comprising a first conductive layer and a second conductive layer; wherein the first conductive layer coats an exposed surface of a corresponding one of the driving electrodes, and a second gap is formed between the first conductive layer and an inner wall surface of the corresponding one of the electrode via-holes; the second conductive layer surrounds a side surface of the first conductive layer and fills the second gap and a third gap, and the third is formed between the first conductive layer and an inner wall surface of the corresponding one of the glass through-holes; the first conductive layer comprises an inert conductor with toughness, and the second conductive layer comprises an elastic conductor;
a light-emitting component layer, comprising a plurality of light-emitting units arranged on a side of the glass substrate away from the driving substrate, wherein an electrode of each of the light-emitting units covers a corresponding one of the conductive portions and is in contact with and electrically connected to the corresponding one of the conductive portions.

2. The display panel according to claim 1, wherein heights of the glass substrate, the first conductive layer, and the second conductive layer away from a side of the driving substrate are different, and both a height difference between the second conductive layer and the first conductive layer and a height difference between the second conductive layer and the glass substrate are in a range of 800 angstroms to 1200 angstroms;
the first gap is in a range of 0.8 micrometers to 1.2 micrometers, and the second gap is in a range of 0.4 micrometers to 0.6 micrometers.

3. The display panel according to claim 2, wherein heights of the glass substrate, the second conductive layer, and the first conductive layer away from the side of the driving substrate are successively increased; or
the heights of the glass substrate, the first conductive layer, and the second conductive layer away from the side of the driving substrate are successively increased; or
the height of the first conductive layer away from the side of the driving substrate is the same as the height of the glass substrate away from the side of the driving substrate, and the second conductive layer is higher than the first conductive layer.

4. The display panel according to claim 3, wherein the second conductive layer extends out of the corresponding one of the glass through-holes along a direction parallel to the glass substrate and partially attach to a side of the glass substrate away from the driving substrate.

5. The display panel according to claim 3, wherein the height of the first conductive layer away from the side of the driving substrate is higher than the height of the second conductive layer away from the side of the driving substrate, and the first conductive layer extends to the second conductive layer along a direction parallel to the glass substrate.

6. The display panel according to claim 1, wherein a material of the first conductive layer comprises a metal or metal oxide, and a material of the second conductive layer comprises a polymer conductive nanomaterial.

7. The display panel according to claim 6, wherein the material of the first conductive layer comprises one or more of silver, gold, copper, copper-silver alloy, nickel-iron alloy, a composite material of nickel ferrite and nickel oxide, nickel ferrite, and a composite material of zinc oxide and zinc ferrite;
the material of the second conductive layer comprises a matrix material and a conductive filler, the matrix material comprises one or more of polydimethylsiloxane, polyethylene terephthalate, polyurethane, and styrene-butadiene-styrene block copolymer, and the conductive filler comprises one or more of gallium-indium-tin alloy, carbon black, a carbon nanotube, graphene, metal powder, a metal nanowire, and a metal nanosheet.

8. The display panel according to claim 1, wherein each of the glass through-holes is coaxially arranged with the corresponding one of the electrode via-holes, and the aperture of each of the glass through-holes is greater than the aperture of the corresponding one of the electrode via-holes; each of the driving electrodes is centered and arranged within an orthographic projection of the corresponding one of the electrode via-holes projected on the driving circuit layer.

9. A manufacturing method, configured to manufacture a display panel, wherein the manufacturing method comprises:
forming a driving substrate, comprising:
providing a silicon substrate and forming a driving circuit layer on the silicon substrate;
forming a bonding electrode layer and an insulating protective layer on the driving circuit layer; wherein the bonding electrode layer comprises a plurality of driving electrodes electrically connected to the driving circuit layer, the insulating protective layer has a plurality of electrode via-holes defined therein, each of the electrode via-holes exposes a corresponding one of the driving electrodes, and a first gap is formed between an inner wall surface of each of the electrode via-holes and the corresponding one of the driving electrodes;
aligning and attaching a glass substrate with a plurality of glass through-holes to the insulating protective layer, so that the glass through-holes are aligned with the electrode via-holes respectively, wherein an aperture of each of the glass through-holes is not smaller than an aperture of a corresponding one of the electrode via-holes;
forming a plurality of conductive portions, each penetrating through a corresponding one of the glass through-holes and a corresponding one of the electrode via-holes, wherein each of the conductive portions comprises a first conductive layer and a second conductive layer; the first conductive layer coats an exposed surface of a corresponding one of the driving electrodes, and a second gap is formed between the first conductive layer and an inner wall surface of the corresponding one of the electrode via-holes; the second conductive layer surrounds a side surface of the first conductive layer and fills the second gap and a third gap, and the third gap is formed between the first conductive layer and an inner wall surface of the corresponding one of the glass through-holes; the first conductive layer comprises an inert conductor with toughness, and the second conductive layer comprises an elastic conductor;
forming a light-emitting component layer on a side of the glass substrate away from the driving substrate, wherein the light-emitting component layer comprises a plurality of light-emitting units, and an electrode of each of the light-emitting units covers a corresponding one of the conductive portions and is in contact with and electrically connected to the corresponding one of the conductive portions.

10. The manufacturing method according to claim 9, wherein the forming a plurality of conductive portions, each penetrating through a corresponding one of the glass through-holes and a corresponding one of the electrode via-holes, comprises:
forming an insulating layer in the corresponding one of the glass through-holes and the corresponding one of the electrode via-holes, so that the insulating layer occupies a position and space for the first conductive layer;
forming the second conductive layer in the corresponding one of the glass through-holes and the corresponding one of the electrode via-holes;
removing the insulating layer;
forming the first conductive layer in the corresponding one of the glass through-holes and the corresponding one of the electrode via-holes.

11. The manufacturing method according to claim 9, wherein the forming a plurality of conductive portions, each penetrating through a corresponding one of the glass through-holes and a corresponding one of the electrode via-holes, comprises:
forming an insulating layer in the corresponding one of the glass through-holes and the corresponding one of the electrode via-holes, so that the insulating layer occupies a position and space for the second conductive layer;
forming the first conductive layer in the corresponding one of the glass through-holes and the corresponding one of the electrode via-holes;
removing the insulating layer;
forming the second conductive layer in the corresponding one of the glass through-holes and the corresponding one of the electrode via-holes.

12. The manufacturing method according to claim 9, wherein the forming a light-emitting component layer on a side of the glass substrate away from the driving substrate, comprises:
depositing a first metal layer on the glass substrate and performing a patterning process to form a plurality of first electrodes, wherein each of the first electrodes covers the corresponding one of the conductive portions and is in contact with and electrically connected to a corresponding one of the conductive portions;
forming a pixel definition layer on the glass substrate and forming a plurality of pixel openings in the pixel definition layer, wherein each of the pixel openings exposes a corresponding one of the first electrodes;
depositing a plurality of light-emitting layers on the first electrodes within the pixel openings respectively;
depositing a second electrode on the pixel definition layer, wherein the second electrode is in contact with and electrically connected to the light-emitting layers, and an edge of the second electrode extends to an edge region of the glass substrate and is in contact with and electrically connected to a corresponding one of the conductive portions.

13. The manufacturing method according to claim 9, wherein heights of the glass substrate, the first conductive layer, and the second conductive layer away from a side of the driving substrate are different, and both a height difference between the second conductive layer and the first conductive layer and a height difference between the second conductive layer and the glass substrate are in a range of 800 angstroms to 1200 angstroms;
the first gap is in a range of 0.8 micrometers to 1.2 micrometers, and the second gap is in a range of 0.4 micrometers to 0.6 micrometers.

14. The manufacturing method according to claim 9, wherein a material of the first conductive layer comprises a metal or metal oxide, and a material of the second conductive layer comprises a polymer conductive nanomaterial.

15. The manufacturing method according to claim 9, wherein each of the glass through-holes is coaxially arranged with the corresponding one of the electrode via-holes, and the aperture of each of the glass through-holes is greater than the aperture of the corresponding one of the electrode via-holes; each of the driving electrodes is centered and arranged within an orthographic projection of the corresponding one of the electrode via-holes projected on the driving circuit layer.

16. A display apparatus, comprising a display panel, wherein the display panel comprises:
a driving substrate, comprising:
a driving circuit layer;
a bonding electrode layer and an insulating protective layer, arranged on a side of the driving circuit layer, wherein the bonding electrode layer comprises a plurality of driving electrodes electrically connected to the driving circuit layer; the insulating protective layer has a plurality of electrode via-holes defined therein, each of the electrode via-holes exposes a corresponding one of the driving electrodes, and a first gap is formed between an inner wall surface of each of the electrode via-holes and the corresponding one of the driving electrodes;
a glass substrate, attached to a side of the insulating protective layer away from the driving circuit layer, wherein the glass substrate has a plurality of glass through-holes defined therein and aligned with the electrode via-holes respectively, and an aperture of each of the glass through-holes is not smaller than an aperture of a corresponding one of the electrode via-holes;
a plurality of conductive portions, each penetrating through a corresponding one of the glass through-holes and a corresponding one of the electrode via-holes, and comprising a first conductive layer and a second conductive layer; wherein the first conductive layer coats an exposed surface of a corresponding one of the driving electrodes, and a second gap is formed between the first conductive layer and an inner wall surface of the corresponding one of the electrode via-holes; the second conductive layer surrounds a side surface of the first conductive layer and fills the second gap and a third gap, and the third is formed between the first conductive layer and an inner wall surface of the corresponding one of the glass through-holes; the first conductive layer comprises an inert conductor with toughness, and the second conductive layer comprises an elastic conductor;
a light-emitting component layer, comprising a plurality of light-emitting units arranged on a side of the glass substrate away from the driving substrate, wherein an electrode of each of the light-emitting units covers a corresponding one of the conductive portions and is in contact with and electrically connected to the corresponding one of the conductive portions.

17. The display apparatus according to claim 16, wherein heights of the glass substrate, the first conductive layer, and the second conductive layer away from a side of the driving substrate are different, and both a height difference between the second conductive layer and the first conductive layer and a height difference between the second conductive layer and the glass substrate are in a range of 800 angstroms to 1200 angstroms;
the first gap is in a range of 0.8 micrometers to 1.2 micrometers, and the second gap is in a range of 0.4 micrometers to 0.6 micrometers.

18. The display apparatus according to claim 16, wherein a material of the first conductive layer comprises a metal or metal oxide, and a material of the second conductive layer comprises a polymer conductive nanomaterial.

19. The display apparatus according to claim 16, wherein the material of the first conductive layer comprises one or more of silver, gold, copper, copper-silver alloy, nickel-iron alloy, a composite material of nickel ferrite and nickel oxide, nickel ferrite, and a composite material of zinc oxide and zinc ferrite;
the material of the second conductive layer comprises a matrix material and a conductive filler, the matrix material comprises one or more of polydimethylsiloxane, polyethylene terephthalate, polyurethane, and styrene-butadiene-styrene block copolymer, and the conductive filler comprises one or more of gallium-indium-tin alloy, carbon black, a carbon nanotube, graphene, metal powder, a metal nanowire, and a metal nanosheet.

20. The display apparatus according to claim 16, wherein each of the glass through-holes is coaxially arranged with the corresponding one of the electrode via-holes, and the aperture of each of the glass through-holes is greater than the aperture of the corresponding one of the electrode via-holes; each of the driving electrodes is centered and arranged within an orthographic projection of the corresponding one of the electrode via-holes projected on the driving circuit layer.
